(19) United States
(12) Patent Application Publication
(10) Pub. No.: US 2008/0238964 A1
(43) Pub. Date: Oct. 2, 2008

(54) DRIVE SIGNAL GENERATING APPARATUS, LIQUID EJECTING APPARATUS, AND DRIVE SIGNAL GENERATING METHOD

(75) Inventor: Atsushi UMEDA, Azumino-shi (JP)

Correspondence Address: SUGHRUE MION, PLLC, 2100 Pennsylvania Avenue, N.W., Washington, DC, 20037, US

(73) Assignee: SEIKO EPSON CORPORATION, Tokyo (JP)

(21) Appl. No.: 12/057,313

(22) Filed: Mar. 27, 2008

(30) Foreign Application Priority Data
Mar. 28, 2007 (JP) 2007-083771

(51) Int. Cl. B41J 29/38; H03K 3/00

(52) U.S. Cl. 347/10; 327/108

(57) ABSTRACT

A drive signal generating apparatus is provided with an analog signal converting section, a current amplification section, and a power source generating section. The analog signal converting section converts digital data to an analog signal. The current amplification section is provided with a current amplification transistor and generates a drive signal by amplifying a current of the analog signal using the current amplification transistor. The power source generating section is a power source having a voltage determined based on the digital data and generates a power source to be supplied to the current amplification transistor.

### CROSS-REFERENCE TO RELATED APPLICATIONS

The present application claims priority upon Japanese Patent Application No. 2007-83771 filed on Mar. 28, 2007, which is herein incorporated by reference.

### BACKGROUND

1. Technical Field

The present invention relates to drive signal generating apparatuses, liquid ejecting apparatuses, and drive signal generating methods.

2. Related Art

There are apparatuses that apply a drive signal to an element targeted for control, thereby causing the element to carry out a desired operation. For example, in an inkjet printer, which is one type of liquid ejecting apparatus, drive signals are applied selectively to piezo elements such that the piezo elements deform to eject ink.

A drive signal generating apparatus that generates a drive signal such as this for example performs current amplification on an analog signal having a desired voltage variation pattern, thereby generating drive signals. A power loss accompanies cases where current amplification is performed using a transistor. Apparatuses have been proposed in which a power source voltage is switched in order to reduce this power loss (for example, see JP-A-2000-218834). In this apparatus, a voltage level of the drive signal is monitored after the drive signal is generated, and the power source is switched based on the voltage level.

In this apparatus, the voltage level of the generated drive signal is used as a reference, which therefore necessitates processing such as converting the voltage of the drive signal to digital values, thereby having a problem of being unsuitable for high speed processing.

### SUMMARY

The present invention has been devised in view of these circumstances, and it is an object thereof to increase a speed of power source switching.

A primary aspect of the present invention for achieving this object is a drive signal generating apparatus provided with:

(A) an analog signal converting section that converts digital data to an analog signal;

(B) a current amplification section that generates a drive signal by amplifying a current of the analog signal, the current amplification section being provided with a current amplification transistor; and

(C) a power source generating section that generates a power source to be supplied to the current amplification transistor, the power source generating section generating a power source of a voltage determined based on the digital data.

Other features of the present invention will become clear through the accompanying drawings and the following description.

### BRIEF DESCRIPTION OF THE DRAWINGS

For a more complete understanding of the present invention and the advantages thereof, reference is now made to the following description taken in conjunction with the accompanying drawings wherein:

FIG. 1 is a block diagram illustrating a configuration of a printing system;

FIG. 2 is a block diagram illustrating a power source section and a drive signal generating circuit and the like;

FIG. 3 is a diagram for describing a drive signal;

FIG. 4 is a diagram for describing DAC data;

FIG. 5 is a diagram for describing a relationship between higher order bits in the DAC data and voltages specified by the DAC data;

FIG. 6 is a diagram for describing a relationship between power source voltages and voltages specified by the DAC data; and

FIG. 7 is a diagram for describing a specific example at a time of generating the drive signal.

### DESCRIPTION OF EXEMPLARY EMBODIMENTS

At least the following matters will be made clear by the description in the present specification and the description of the accompanying drawings.

Namely, it will be made clear that a drive signal generating apparatus can be achieved provided with: (A) an analog signal converting section that converts digital data to an analog signal; (B) a current amplification section that generates a drive signal by amplifying a current of the analog signal, the current amplification section being provided with a current amplification transistor; and (C) a power source generating section that generates a power source to be supplied to the current amplification transistor, the power source generating section generating a power source of a voltage determined based on the digital data.

With this drive signal generating apparatus, digital data based on the drive signal is used in determining the voltage of the power source to be supplied to the current amplification transistor. Thus there is no need to carry out a process such as obtaining a voltage of the drive signal and a higher speed of processing can be achieved.

In this drive signal generating apparatus, it is preferable that the digital data indicates a voltage of the drive signal using a plurality of bits, and the power source generating section includes a power source generating circuit that generates a plurality of power sources each having different voltages, and a power source selection circuit that selectively supplies the plurality of power sources based on a content of a portion of bits constituting the digital data.

With this drive signal generating apparatus, digital data is used in a plurality of applications and therefore simplification of control is achieved.

In this drive signal generating apparatus, a configuration is preferable in which the digital data is received for each of the bits, and a switch circuit of the power source selection circuit controls supply of a power source of a certain voltage in response to a voltage level indicated by the bits.

With this drive signal generating apparatus, it is possible to reliably select an appropriate power source among the plurality of power sources of different voltages.

In this drive signal generating apparatus, a configuration is preferable in which the digital data indicates higher voltages of the drive signal using a higher order bit, and the power source selection circuit uses the higher order bit to control supply of a power source having a higher voltage than a power source whose supply is controlled by a lower order side bit than the higher order bit.

With this drive signal generating apparatus, the control of supply for higher voltage side power sources is handled by higher order bits used in specifying higher voltage side voltages. Thus correlativity can be achieved between the voltage specified by the digital data and the power source to be supplied such that control is simplified.

In this drive signal generating apparatus, a configuration is preferable in which the power source selection circuit selects a power source having a closest voltage to a voltage of the drive signal from among the power sources having voltages higher than the voltage of the drive signal.

With this drive signal generating apparatus, power loss in the current amplification transistor can be effectively suppressed.

In this drive signal generating apparatus, a configuration is preferable in which the current amplification transistor includes an NPN transistor whose collector is connected to a supply line of the power source that has been generated by the power source generating section, whose emitter is connected to a supply line of the drive signal, and whose base is connected to a supply line of the analog signal.

With this drive signal generating apparatus, heat generation in the NPN transistor can be suppressed.

Furthermore, it will be made clear that a following liquid ejecting apparatus can be achieved.

Namely, it will be made clear that a liquid ejecting apparatus can be achieved provided with: (A) an analog signal converting section that converts digital data to an analog signal; (B) a current amplification section that generates a drive signal by amplifying a current of the analog signal, the current amplification section being provided with a current amplification transistor; (C) a power source generating section that generates a power source to be supplied to the current amplification transistor, the power source generating section generating a power source of a voltage that has been determined based on the digital data; and (D) a head that ejects a liquid due to application of the drive signal.

Also, it will be made clear that a following drive signal generating method can be achieved.

Namely, it will be made clear that a drive signal generating method can be achieved, including (A) generating a plurality of power sources each having different voltages; (B) converting digital data to an analog signal; (C) selecting based on the digital data and supplying to a current amplification transistor a power source having a corresponding voltage from among the plurality of power sources; and (D) generating a drive signal by amplifying a current of the analog signal using the current amplification transistor.

### First Embodiment

Regarding the Drive Signal Generating Apparatus

The drive signal generating apparatus generates a drive signal that is applied to an element targeted for control. The drive signal generating apparatus is incorporated for example in a liquid ejecting apparatus that ejects a liquid. Examples of liquid ejection apparatuses include printing apparatuses, color filter manufacturing apparatuses, display manufacturing apparatuses, semiconductor manufacturing apparatuses, and DNA chip manufacturing apparatuses. In liquid ejecting apparatuses such as these, a piezo element is provided for example, which serves as an element that is driven in order to cause a liquid to be ejected.

In the present specification, description is given using as an example a liquid ejecting apparatus in which the drive signal generating apparatus has been incorporated. Specifically, description is given using as an example an inkjet printer (hereinafter, also referred to simply as a “printer”) as a printing apparatus.

System Configuration

Regarding the Printing System

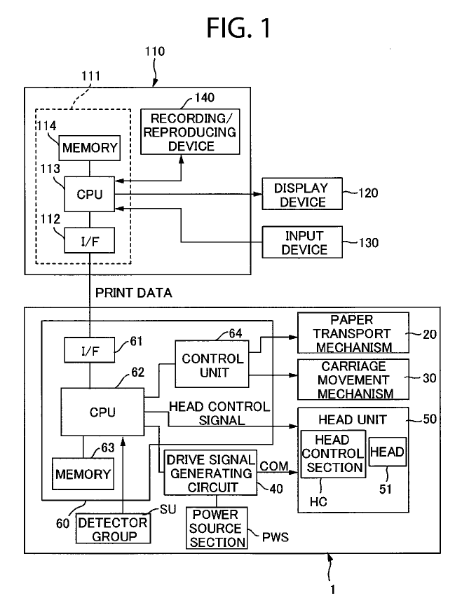

FIG. 1 is a block diagram illustrating a configuration of a printing system. The illustrated printing system includes a printer 1, a computer 110, a display device 120, an input device 130, and a recording/reproducing device 140. The printer 1 corresponds to the printing apparatus and prints images on media such as paper, cloth, and film. The medium is a target object targeted for ejection of liquid, and for example is paper. The computer 110 is communicably connected to the printer 1. In order to print an image with the printer 1, the computer 110 sends print data corresponding to that image to the printer 1. The display device 120 is a liquid crystal display or the like. The input device 130 is a keyboard or the like. The recording/reproducing device 140 is a flexible disk drive device or the like.

Regarding the Computer 110

The computer 110 includes a host-side controller 111. The host-side controller 110 performs various controls in the computer 110. The host-side controller 111 has an interface section 112, a CPU 113, and a memory 114. The interface section 112 exchanges data with the printer 1. The CPU 113 performs overall control of the computer 110. The memory 114 is for ensuring a working region and a region for storing the computer programs used by the CPU 113. The CPU 113 performs various controls in accordance with the computer programs stored in the memory 114.

Print data is data in a format that can be interpreted by the printer 1, and includes various kinds of command data as well as dot formation data. “Command data” refers to data for instructing the printer 1 to carry out a specific operation. Examples of the command data include command data for directing paper-supplying, command data indicating a transport amount, and command data for directing paper discharge. Moreover, dot formation data is data relating to the dots to be formed on the paper (data such as the color and the size of the dots).

Regarding the Printer 1

The printer 1 includes a paper transport mechanism 20, a carriage movement mechanism 30, a drive signal generating circuit 40, a head unit 50, a detector group SU, a printer-side controller 60, and a power source section PWS.

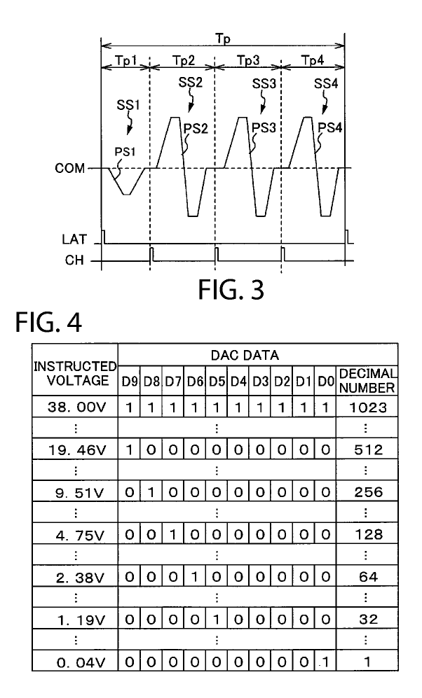

The paper transport mechanism 20 transports the paper as a medium in a transport direction. The carriage movement mechanism 30 moves the head unit 50 in a predetermined direction (for example, a paper width direction). A head 51 provided in the head unit 50 ejects ink, which is one type of liquid, toward the paper. The drive signal generating circuit 40 generates a drive signal COM. The drive signal COM is used when printing onto the paper and, as shown in FIG. 3, is a serial signal that includes a micro-vibration pulse PS1 and ejection pulses PS2 to PS4. It should be noted the drive signal generating circuit 40 and the drive signal COM that is generated are described later.

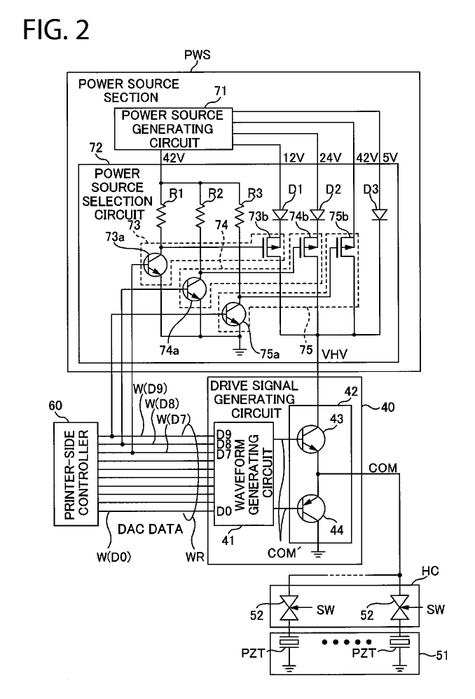

The head unit 50 has a head control section HC and the head 51. As shown in FIG. 2, the head 51 is provided with piezo elements PZT. The piezo elements PZT correspond to elements that are driven to cause a liquid to be ejected and a plurality of these are arranged corresponding to nozzles (not shown in diagram) provided in the head 51. For example, from 96 to 180 piezo elements PZT are arranged corresponding to the ink of one color. These piezo elements PZT are one type of capacitive elements that can hold an electric charge and deform in accordance with charging and discharging. Due to this deformation, the piezo elements PZT cause a pressure change on ink that is stored in a pressure chamber (not shown in diagram) inside the head 51. Due to this pressure change, ink is ejected from the nozzle.

The head control section HC selectively applies to the piezo elements PZT necessary portions of the drive signal COM, which has been generated by the drive signal generating circuit 40. For this reason, the head control section HC is provided with a plurality of switches 52 arranged respectively corresponding to the piezo elements PZT midway on a supply line of the drive signal COM. Then, the head control section HC selectively applies to the piezo elements PZT necessary portions of the drive signal COM by controlling these switches 52. At this time a desired amount of ink can be ejected from the nozzles according to the manner in which the necessary portions are selected.

The detector group SU is constituted by a plurality of detectors that monitor conditions of the printer 1. Detection results of these detectors are outputted to the printer-side controller 60. The printer-side controller 60 controls the sections targeted for control based on the print data received from the computer 110 and the detection results of these detectors so as to print an image on the paper. It should be noted that the printer-side controller 60 is described later.

The power source section PWS generates a power source to be supplied to current amplification transistors provided in the drive signal generating circuit 40. It should be noted that the power source section PWS also is described later.

Principal Components of the Printer 1

Regarding the Printer-side Controller 60

The printer-side controller 60 performs overall control in the printer 1. For example, the printer-side controller 60 controls the paper transport mechanism 20, the carriage movement mechanism 30, the drive signal generating circuit 40, and the head unit 50. As shown in FIG. 1, the printer-side controller 60 includes an interface section 61, a CPU 62, a memory 63, and a control unit 64. The interface section 61 exchanges data with the computer 110, which is an external apparatus. The CPU 62 is a computation processing unit for performing the overall control of the printer 1. The memory 63 is for reserving an area for storing programs for the CPU 62 and a working area, for example, and is constituted by a storage element such as a RAM, an EEPROM, or a ROM.

The CPU 62 controls the sections to be controlled according to computer programs stored in the memory 63. For example, the CPU 62 controls the paper transport mechanism 20 and the carriage movement mechanism 30 via the control unit 64. Furthermore, the CPU 62 sends head control signals for controlling the operation of the head 51 to the head control section HC and sends a control signal for generating the drive signals COM to the drive signal generating circuit 40.

The control signals for generating the drive signals COM are also referred to as DAC data and are constituted by multi-bit digital data. In the present embodiment, the DAC data is constituted by 10-bit digital data. For convenience, in the following description, the least significant bit of the DAC data is also referred to as data D0 and the most significant bit is also referred to as data D9. The DAC data is data for determining a voltage waveform of the drive signals COM generated by the drive signal generating circuit 40. Specifically, it is data for determining a voltage of a voltage waveform signal COM′ (analog signal) generated by a waveform generating circuit 41 (see FIG. 2) provided in the drive signal generating circuit 40. The DAC data indirectly indicates a voltage value of the drive signals COM and corresponds to waveform generating information for determining a waveform of the drive signals COM. The content of the DAC data is updated at each of extremely short update cycles. For example, it is updated at each update cycle (approximately each 0.04 μs) prescribed by a 24 MHz DAC clock (DAC_CLK). Since the DAC data is digital data indicating voltage values, the printer-side controller 60 can identify the voltage to be used in controlling the drive signals COM based on the content of the DAC data that is sent. The DAC data is stored in a predetermined area of the memory 63 and is read out to the CPU 62 when generating the drive signals COM. In this case, the predetermined area of the memory 63 corresponds to a DAC data storage section.

DAC data that has been read out is sent via a signal line group WR and received by the drive signal generating circuit 40 (specifically, the waveform generating circuit 41). Here, the DAC data is sent and received in parallel in bit units (for each bit). Thus, as shown in FIG. 2, the signal line group WR for the DAC data is constituted by 10 signal lines respectively corresponding to the bits of DAC data. That is, the signal line group WR is constituted by a signal line W(D0) for data D0 to a signal line W(D9) for data D9.

Regarding the Drive Signal Generating Circuit 40

The drive signal generating circuit 40 corresponds to a drive signal generating section that generates the drive signals COM. As shown in FIG. 2, the drive signal generating circuit 40 is provided with the waveform generating circuit 41 and a current amplification circuit 42. The waveform generating circuit 41 generates the voltage waveform signal COM′ in a voltage variation pattern determined by the DAC data (waveform generating information). The voltage waveform signal COM′ is a signal having a voltage waveform that is a basis of the drive signals COM. The waveform generating circuit 41 is constituted by a digital-analog converter and converts DAC data, which is digital data, into the voltage waveform signal COM′, which is an analog signal. Thus, the waveform generating circuit 41 corresponds to an analog signal converting section that converts digital data to analog signals.

The waveform generating circuit 41 is provided with input terminals for DAC data and output terminals for the voltage waveform signals COM′. In the present embodiment, the DAC data input terminals are arranged as 10 channels corresponding to the signal line W(D0) to signal line W(D9) respectively for sending and receiving DAC data. Furthermore, the voltage waveform signal COM′ output terminals are arranged as two channels. This is because the voltage waveform signal COM′ is used in two transistors 43 and 44 that constitute the current amplification circuit 42.

As shown in FIG. 4, the waveform generating circuit 41 of the present embodiment generates a voltage waveform signal COM′ of 0.04V when 10-bit DAC data [0000000001] is received. And each time the value of the DAC data increases by [1], a voltage waveform signal COM′ is generated that is approximately 0.037V higher in voltage. That is, higher order bits are used and larger values are determined in the DAC data for higher voltages of the voltage waveform signal COM′. For example, when DAC data [0000100000] is received, the waveform generating circuit 41 generates a voltage waveform signal COM′ of 1.19V. Furthermore, when DAC data [0010000000] is received, the waveform generating circuit 41 generates a voltage waveform signal COM′ of 4.75V. Similarly, when DAC data [1111111111] is received, the waveform generating circuit 41 generates a voltage waveform signal COM′ of 38.00V.

The current amplification circuit 42 corresponds to a current amplification section that amplifies the current of the voltage waveform signal COM′, which is an analog signal, and outputs this as the drive signal COM. The current amplification circuit 42 is provided with an NPN transistor 43 and a PNP transistor 44, which are complementarily connected, as the current amplification transistors. The NPN transistor 43 operates when the voltage of the drive signal COM increases (when the piezo elements PZT are charging during printing). A collector of the NPN transistor 43 is connected to a supply line of the power source and its emitter is connected to a supply line of the drive signal COM. And a base of the NPN transistor 43 is connected to a supply line of the voltage waveform signal COM′. The PNP transistor 44 operates when the voltage of the drive signal COM decreases (similarly, when the piezo elements PZT are discharging). An emitter of the PNP transistor 44 is connected to a supply line of the drive signal COM, and its collector is grounded. And a base of the PNP transistor 44 is connected to a supply line of the voltage waveform signal COM′.

In the thus-configured current amplification circuit 42, operations of the transistors 43 and 44 are controlled according to the voltage waveform signal COM′ outputted from the waveform generating circuit 41. As a result, the voltage of the drive signal COM outputted from the current amplification circuit 42 fluctuates slightly in the current amplification process, but is substantially equivalent to the voltage of the voltage waveform signal COM′. And the voltage of the voltage waveform signal COM′ is specified by the DAC data as digital data. Consequently, the DAC data can be considered to be multi-bit data (10-bit in the present embodiment) that indirectly indicates the voltage of the drive signal COM. As mentioned earlier, larger values are determined in the DAC data for higher voltages of the voltage waveform signal COM′. Thus, larger values are determined in the DAC data for higher voltages of the drive signal COM. For convenience, in the following description, the voltage of the voltage waveform signal COM′ indicated by the DAC data may also be referred to as instructed voltage. The instructed voltage corresponds to voltage information used in control.

Regarding the Drive Signal COM

Here description is given concerning the drive signal COM. As shown in FIG. 3, the drive signal COM is generated repetitively for each print time period Tp, which is also a repetitive unit. The drive signal COM is constituted by four waveform portions SS1 to SS4. That is, the drive signal COM has a first waveform portion SS1 generated in a time period Tp1, a second waveform portion SS2 generated in a time period Tp2, a third waveform portion SS3 generated in a time period Tp3, and a fourth waveform portion SS4 generated in a time period Tp4. The waveform portions SS1 to SS4 have constant voltage portions and drive pulses. The constant voltage portions are portions fixed to a reference voltage and the drive pulses have a voltage variation pattern for causing predetermined operations of the piezo elements PZT. In the drive signal COM, the first waveform portion SS1 has a micro-vibration pulse PS1 and the second waveform portion SS2 has a first ejection pulse PS2. The third waveform portion SS3 has a second ejection pulse PS3, and the fourth waveform portion SS4 has a third ejection pulse PS4. The micro-vibration pulse PS1 and the ejection pulses PS2 to PS4 are all types of drive pulses. The micro-vibration pulse PS1 causes a micro-vibration operation to be carried out in the piezo elements PZT so as to prevent thickening of the ink. And the ejection pulses PS2 to PS4 cause an ink ejection operation (corresponding to a liquid ejection operation) to be carried out in the piezo elements PZT so as to eject a predetermined amount of ink from the nozzles of the head 51. And by selectively applying the waveform portions SS1 to SS4 to the piezo elements PZT, different amounts of ink can be ejected and operations to suppress thickening of ink can be performed.

Regarding the Power Source Section PWS

The power source section PWS corresponds to a power source generating section and generates a power source to be supplied to the current amplification transistors. And the power source section PWS of the printer 1 has a characteristic in the point that it generates a power source of a voltage determined based on the DAC data (digital data).

As shown in FIG. 2, the power source section PWS is provided with a power source generating circuit 71 and a power source selection circuit 72. The power source generating circuit 71 generates a plurality of power sources having different voltages. In the example here, power sources of four voltages are generated, constituted by 5V, 12V, 24V, and 42V. It should be noted in regard to the 42V power source that two types are generated. One is used for determining a gate voltage of FETs 73b to 75b provided in the power source selection circuit 72 and the other is supplied to the current amplification transistor (NPN transistor 43) provided in the current amplification circuit 42. In other words, the other 42V power source is a current source. Furthermore, the 5V, 12V, and 24V power sources are also power sources (current sources) supplied to the current amplification transistors.

The power source selection circuit 72 selects a target power source among the four power sources, which are current sources. The power source selected by the power source selection circuit 72 is supplied to the current amplification transistors. The power source selection circuit 72 selects from the plurality of power sources based on the content of a portion of bits constituting the DAC data, that is, voltage information indicated by specific bits. In short, in addition to being used as information for specifying voltage, the DAC data is also used as information for power source selection. For example, the power source selection circuit 72 selects the 42V power source based on the content of the data D9, which is the most significant bit. Furthermore, the 24V power source is selected based on the content of the data D8, which is the second bit from the high order side, and supply of the 12V power source is selected based on the content of the data D7, which is the third bit. It should be noted that this point is described in detail later.

The illustrated power source selection circuit 72 is provided with a switch circuit group, a pull-up resistor group, and a diode group. The switch circuit group is provided with a first switch circuit 73, a second switch circuit 74, and a third switch circuit 75. The pull-up resistor group is provided with a first pull-up resistor R1, a second pull-up resistor R2, and a third pull-up resistor R3. The diode group is provided with a first diode D1, and a second diode D2, and a third diode D3.

Regarding the Switch Circuit Group

The switch circuits 73 to 75 that constitute the switch circuit group are arranged corresponding to the plurality of power sources. In the power source section PWS, the switch circuits 73 to 75 are arranged corresponding to three power sources among the four power sources, which are current sources, excluding the 5V power source, which is the lowest power source. That is, the first switch circuit 73 is arranged corresponding to the 12V power source, which is the second lowest, and the second switch circuit 74 is arranged corresponding to the 24V power source, which is the third lowest. Furthermore, the third switch circuit 75 is arranged corresponding to the 42V power source, which is the highest power source. And the switch circuits 73 to 75 control the supply of their corresponding power sources.

Each of the switch circuits 73 to 75 is constituted by a transistor as a first switching element and a FET as a second switching element. For example, the first switch circuit 73 is provided with an NPN transistor 73a and a P-channel FET 73b.

The collector of the NPN transistor 73a provided in the first switch circuit 73 is connected via the first pull-up resistor R1 to the power source generating circuit 71. Specifically, it is connected to a supply terminal for supplying the power source for the gate voltage (that is, one of the 42V power sources). The base of the NPN transistor 73a is connected to one of the signal lines constituting the signal line group WR for DAC data. Specifically, it is connected to the signal line W(D7) for the data D7. And the emitter of the NPN transistor 73a is grounded. Accordingly, the NPN transistor 73a is unconnected when the data D7 of the DAC data is L level (value [0]). In this way, the voltage of the collector indicates 42V due to the power source for the gate voltage. On the other hand, the NPN transistor 73a is connected when the data D7 of the DAC data is H level (value [1]). In this way, the voltage of the collector indicates the ground (0V).

The source of the P-channel FET 73b provided in the first switch circuit 73 is connected to the supply line for supplying the 12V power source and its gate is connected to the collector of the NPN transistor 73a. Furthermore, its drain is connected to the current amplification transistor (the collector of the NPN transistor 43). And the first diode D1 is connected midway on the supply line for supplying the 12V power source. In regard to the first diode D1, its anode is connected to the power source generating circuit 71 and its cathode is connected to the P-channel FET 73b side. The P-channel FET 73b operates when its gate voltage becomes lower than its source voltage by a predetermined bias or more. During operation, the P-channel FET 73b causes connection between the source and drain. On the other hand, when the gate voltage is higher than the operation voltage, the P-channel FET 73b blocks between the source and drain. In this manner, the P-channel FET 73b functions as a switch that operates in response to the gate voltage. Accordingly, in an operational state, the 12V power source, which is a current source, is supplied to the current amplification transistors.

It should be noted that the other switch circuits also have the same configuration. To describe this simply, the collector of the NPN transistor 74a provided in the second switch circuit 74 is connected via the second pull-up resistor R2 to the supply terminal of the power source for the gate voltage. And the base of the NPN transistor 74a is connected to the signal line W(D8) for the data D8 and its emitter is grounded. Accordingly, the NPN transistor 74a is unconnected when the data D0 is L level and is connected when the data D8 is H level. The source of the P-channel FET 74b provided in the second switch circuit 74 is connected via the second diode D2 to the supply line for supplying the 24V power source, and its gate is connected to the collector of the NPN transistor 74a. Furthermore, its drain is connected to the current amplification transistor. The P-channel FET 74b also functions as a switch that operates in response to the gate voltage. Accordingly, in an operational state, the 24V power source, which is a current source, is supplied to the current amplification transistors.

The collector of the NPN transistor 75a provided in the third switch circuit 75 is connected via the third pull-up resistor R3 to the supply terminal of the power source for the gate voltage. And the base of the NPN transistor 75a is connected to the signal line W(D9) for the data D9 and its emitter is grounded. Accordingly, the NPN transistor 75a is unconnected when the data D9 is L level and is connected when the data D9 is H level. The source of the P-channel FET 75b provided in the third switch circuit 75 is connected to the supply line for supplying the 42V power source and its gate is connected to the collector of the NPN transistor 75a. Furthermore, its drain is connected to the current amplification transistor. The P-channel FET 75b also functions as a switch that operates in response to the gate voltage. Accordingly, in an operational state, the current source 42V power source is supplied to the current amplification transistors.

In this manner, the power source selection circuit 72 uses the DAC data, which indicates the voltage of the voltage waveform signal COM′ (drive signal COM) to select the power source. Accordingly, the DAC data can be considered to have a function of indicating the voltage of the voltage waveform signal COM′ and a function of selecting the power source. With this configuration, there is no need to generate a special purpose control signal in order to select the power source and thus simplification of control is achieved.

Also, the power source selection circuit 72 is provided with a plurality of switch circuits associated with predetermined power sources. These switch circuits 73 to 75 control the supply and blocking of their corresponding power sources and their operation is controlled by different bit data in the DAC data respectively. In this manner, since the power sources are associated with a certain bit in the DAC data, it is possible to reliably select an appropriate power source among the plurality of power sources of different voltages.

Furthermore, in selecting the power source, the certain bit that constitutes the DAC data controls the supply of a power source having a higher voltage than the power sources whose supply is controlled by lower order bits than the certain bit. In other words, the control of supply for higher voltage side power sources is handled by higher order bits used in specifying higher voltage side voltages. This enables correlativity to be achieved between the voltage specified by the DAC data and the power source to be supplied, and therefore control is simplified.

Regarding the Pull-up Resistor Group and Diode Group The pull-up resistor group is for determining the gate voltage of each of the P-channel FETs 73b to 75b. That is, in the non-operating state of its corresponding P-channel FET, each of the pull-up resistors R1 to R3 determines a gate voltage of a higher voltage than the operation voltage of that P-channel FET. Furthermore, in the operating state of its corresponding P-channel FET, a gate voltage is determined that is equal to or less than the operation voltage of that P-channel FET. Thus, the resistance value of the pull-up resistors R1 to R3 makes it possible to determine that a desired switching operation is carried out. To describe this simply, when the data D8 and the data D9 are L level and the data D7 is H level, the first pull-up resistor R1 corresponding to the first switch circuit 73 is set to a resistance value that causes an operating state of the P-channel FET 73b of the first switch circuit 73. When the data D9 is L level and the data D8 is H level, the second pull-up resistor R2 corresponding to the second switch circuit 74 is set to a resistance value that causes an operating state of the P-channel FET 74b of the second switch circuit 74. When the data D9 is H level, the third pull-up resistor R3 corresponding to the third switch circuit 75 is set to a resistance value that causes an operating state of the P-channel FET 75b of the third switch circuit 75.

The diode group prevents the current from flowing in a reverse direction. In this power source section PWS, the higher order bits (data D7 to data D9) of the DAC data are used as signals for selecting the power source. For this reason, depending on the DAC data, two or more P-channel FETs may be in an operating state. At this time, it is necessary to prevent the current from flowing from the higher voltage side power source to the lower voltage side power source. The diodes D1 to D3 of the diode group can be used to prevent reverse direction current such as this. That is, the first diode D1 prevents reverse direction current for the 12V power source. Furthermore, the second diode D2 prevents reverse direction current for the 24V power source, and the third diode D3 prevents reverse direction current for the 5V power source.

Regarding Operation of the Power Source Section PWS

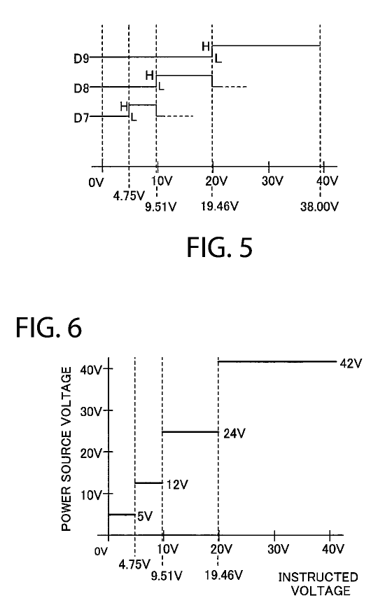

Next, description is given regarding operation of the power source section PWS. As shown in FIG. 4, the data D9, which is the most significant bit of the DAC data, switches from the value [0] to the value [1] at a timing at which the instructed voltage (the voltage of the voltage waveform signal COM′ indicated by the DAC data) becomes 19.46V. After this, the data D9 maintains the value [1] until the instructed voltage reaches 38.00V. Accordingly, as shown in FIG. 5, the voltage level of the data D9 is L level until the instructed voltage reaches 19.46V. And it becomes H level when the instructed voltage is equal to or higher than 19.46V. As shown in FIG. 4, the data D8, which is the second highest order bit, switches from the value [0] to the value [1] at a timing at which the instructed voltage becomes 9.51V, and maintains the value [1] until the instructed voltage reaches immediately before 19.46V. When the instructed voltage reaches 19.46V, the data D8 returns to the value [0]. After this, it switches to the value [1] in accordance with rises in the instructed voltage. Specifically, when from [1100000000] until [1111111111] is received as the DAC data, the data D8 switches to the value [1]. As shown in FIG. 4, the data D7, which is the third highest order bit, switches from the value [0] to the value [1] at a timing at which the instructed voltage becomes 4.75V, and maintains the value [1] until the instructed voltage reaches immediately before 9.51V. When the instructed voltage reaches 9.51V, the data D7 returns to the value [0] and switches to the value [1] in accordance with rises in the instructed voltage. This aspect is substantially the same as for the data D8, and therefore specific description thereof is omitted.

The data D7 to data D9 function as control signals that control the operation of the switch circuits. In other words, they function as control signals that control the supply of the corresponding power source. For example, as shown in FIG. 6, when the instructed voltage is less than 4.75V, the 5V power source is supplied to the current amplification transistors. When the instructed voltage is equal to or more than 4.75 but less than 9.51, the data D7 is H level. Thus, the P-channel FET 73b of the first switch circuit 73 is connected. In accordance with this, the 12V power source is supplied to the current amplification transistors. Here, the third diode D3 is connected midway on the supply line for supplying the 5V power source. For this reason, the flow of current into the power source generating circuit 71 side is prevented even if the 12V power source is supplied.

When the instructed voltage is equal to or more than 9.51V but less than 19.46V, the data D8 is H level. Thus, the P-channel FET 74b of the second switch circuit 74 is connected. In accordance with this, the 24V power source is supplied to the current amplification transistors. At this time, the flow of current into the power source generating circuit 71 side is prevented by the first diode D1 and the third diode D3. When the instructed voltage is equal to or more than 19.46V, the data D9 is H level. Thus, the P-channel FET 75b of the third switch circuit 75 is connected. In accordance with this, the 42V power source is supplied to the current amplification transistors. At this time, the flow of current into the power source generating circuit 71 is prevented by the first diode D1 to the third diode D3 respectively.

As is evident from the above description, the power source selection circuit 72 can be said to be selecting the power source having the closest voltage to the voltage of the drive signal COM from among the power sources having voltages higher than the voltage of the voltage waveform signal COM′ (in other words, the voltage of the drive signal COM).

### Regarding a Specific Example of Operation

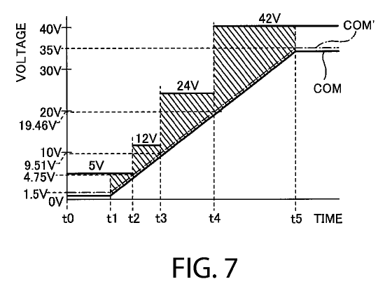

Next, description is given based on a specific example concerning a relationship between the power sources, which are current sources, and the current amplification transistors. FIG. 7 illustrates a relationship among the voltage waveform signal COM′, the drive signal COM, and the power source that is supplied. In FIG. 7, the horizontal axis indicates time and the vertical axis indicates voltage. And the solid line, which indicates the voltage value, also indicates that power source that is supplied. Furthermore, the dashed dotted line, which is indicated by the reference symbol COM′, indicates the voltage waveform signal COM′ (analog signal) and the solid line, which is indicated by the reference symbol COM, indicates the drive signal COM.

In this specific example, the voltage waveform signal COM′ is regulated to 1.5V from a timing t0 until a timing t1. And the voltage is caused to rise at a fixed rate from the timing t1 until a timing t5. In this way, the voltage waveform signal COM′ is regulated to 35V when the timing t5 is reached and from the timing t5 onward. The drive signal COM is regulated to a voltage lower than this by a voltage drop proportion of the current amplification NPN transistor 43. In this specific example, the voltage of the drive signal COM is regulated to a voltage approximately 0.6V lower than the voltage waveform signal COM′.

The voltage waveform signal COM′ is fixed at 1.5V throughout a time period from the timing t0 until the timing t1. In this time period, all the values of the data D7 to data D9 in the DAC data are the value [0]. For this reason, the power sources are blocked by the first switch circuit 73 to the third switch circuit 75 respectively. As a result, the 5V power source is supplied to the collector of the NPN transistor 43. Furthermore, in this time period, the voltage waveform signal COM′ is a fixed voltage, and therefore the NPN transistor 43 does not operate.

When the timing t1 passes, the voltage of the voltage waveform signal COM′ rises at a fixed rate. In accordance with this, the NPN transistor 43 operates. In other words, current is flowed to the piezo elements PZT side such that the voltage of the drive signal COM rises at an equivalent rate in line with the rising voltage of the voltage waveform signal COM′. Thus, collector loss is produced in the NPN transistor. The collector loss can be obtained by multiplying a voltage difference between the power source and the drive signal COM by the collector current (that is, the current that is flowed when the piezo elements PZT are charging). In this specific example, the voltage of the power source is 5V in the time period until the timing t2 is reached. Thus, the collector loss can be obtained by multiplying the difference between the power source voltage (5V) and the drive signal COM voltage (the voltage difference indicated by hatching) by the amount of current that is flowed into the piezo elements PZT side.

At the timing t2, the voltage of the voltage waveform signal COM′ becomes 4.75V. In other words, the data D7 in the DAC data is the value [1]. For this reason, the 12V power source is supplied to the collector of the NPN transistor 43. In accordance with this, the collector loss can be obtained by multiplying the voltage difference based on 12V, which is the power source voltage, by the amount of current that is flowed into the piezo elements PZT side.

Thereafter, the power source is switched in a same manner. At the timing t3, the voltage of the voltage waveform signal COM′ becomes 9.51V and the data D8 is the value [1]. For this reason, the 24V power source is supplied to the collector of the NPN transistor 43. Furthermore, at the timing t4, the voltage of the voltage waveform signal COM′ becomes 19.46V and the data D9 is the value [1]. For this reason, the 42V power source is supplied to the collector of the NPN transistor 43.

By carrying out control in this manner, the voltage of the drive signal COM rises throughout the time period from the timing t1 until the timing t5. Here, the power source selected as the power source to be supplied to the collector of the NPN transistor 43 is the power source having the closest voltage to the voltage of the drive signal COM from among the power sources having voltages higher than the voltage of the drive signal COM. In this specific example, the 5V power source is selected in the time period from the timing t1 until the timing t2, and the 12V power source is selected in the time period from the timing t2 until the timing t3. Similarly, the 24V power source is selected in the time period from the timing t3 until the timing t4, and the 42V power source is selected in the time period from the timing t4 onward. In this way, the voltage difference between the collector and the emitter of the NPN transistor 43 can be reduced during voltage rises of the drive signal COM, and collector loss can be suppressed. As a result, power consumption in the current amplification circuit 42 can be reduced. That is, excessive heat generation by the NPN transistor 43 can be suppressed.

At this time, the selection of the power source is carried out using a portion of the bits (3 highest order bits) of the DAC data. In this way, the DAC data can be used as a control signal, and therefore there is no need to carry out a process such as generating a control signal based on the voltage of the drive signal COM, thereby achieving higher speeds of processing. Furthermore, there is no need to generate a special-purpose control signal, and therefore configuration simplification is also achieved.

It should be noted that in the foregoing description is given using the drive signal COM of FIG. 7 as an example, but the drive signal COM used in printing operations have a voltage variation pattern shown in FIG. 3 for example. Equivalent effects and results are also achieved with a drive signal COM having a voltage variation pattern such as this.

### SUMMARY

As described above, the printer 1 is provided with the waveform generating circuit 41 as the analog signal converting section, the current amplification circuit 42 as the current amplification section, and the power source section PWS as the power source generating section. And the waveform generating circuit 41 converts the DAC data, which is digital data, into the voltage waveform signal COM′, which is an analog signal. The current amplification circuit 42 uses the pair of transistors, which are the current amplification transistors, and amplifies the current of the voltage waveform signal COM′ to carry out generation of the drive signal COM. Then, the drive signal COM that is generated is outputted. The power source section PWS generates the power source to be supplied to the current amplification transistors. Here, the voltage of the power source to be supplied to the pair of transistors (specifically, the NPN transistor 43) is determined using the DAC data, which is a basis of the drive signal COM. In this way, there is no need to carry out a process such as obtaining a voltage value from the drive signal COM and a higher speed of processing can be achieved.

Furthermore, in the printer 1, the DAC data indicates the voltage of the voltage waveform signal COM′ (drive signal COM) using 10 bits. Furthermore, the power source section PWS is provided with the power source generating circuit 71, which generates a plurality of power sources of different voltages, and the power source selection circuit 72, which selectively supplies the plurality of power sources based on the content of a portion of bits constituting the DAC data. In this manner, the DAC data is also used as information for selecting the power source, and therefore simplification of control is achieved. Furthermore, it is also possible to select an appropriate power source in response to the DAC data.

And the power source selection circuit 72 selects the power source having the closest voltage to the voltage of the drive signal COM from among the power sources having voltages higher than the voltage of the voltage waveform signal COM′ (in other words, the voltage of the drive signal COM), and therefore power loss in the current amplification transistors (the NPN transistor 43) can be effectively suppressed.

### Other Embodiments

The foregoing embodiment describes a printing system provided with the printer 1, but therein also includes disclosure of a drive signal COM generating method and a power source section PWS control method and the like. Moreover, the foregoing embodiment is merely for facilitating the understanding of the present invention, but is not meant to be interpreted in a manner limiting the scope of the present invention. It goes without saying that the invention can be altered and improved without departing from the gist thereof and includes functional equivalents.

Regarding the Current Amplification Section

In the foregoing embodiment, the current amplification circuit 42 having the NPN transistor and the PNP transistor was illustrated as an example of the current amplification section. As long as it is a configuration provided with a current amplification transistor, the current amplification section is not limited to the configuration of the current amplification circuit 42.

Regarding Other Apparatuses

The printer 1 in the foregoing embodiment was of a form that carries out printing by causing the head 51 to move in a reciprocating manner in a carriage movement direction, but there is no limitation to this configuration. For example, a line head printer 1 is also possible having a line head in which a plurality of nozzles are arranged extending in a width direction of the medium.

Furthermore, as long as it is an apparatus having an element driven by the drive signal COM, there is no limitation to the printer 1 (liquid ejecting apparatus). For example, the present invention is also applicable to a micro pump, a sounding body (a speaker or the like), and a micro actuator, which use this element.

Although the preferred embodiment of the present invention has been described in detail, it should be understood that various changes, substitutions and alterations can be made therein without departing from spirit and scope of the inventions as defined by the appended claims.

What is claimed is:

1. A drive signal generating apparatus, comprising:
(A) an analog signal converting section that converts digital data to an analog signal;
(B) a current amplification section that generates a drive signal by amplifying a current of the analog signal, the current amplification section being provided with a current amplification transistor; and
(C) a power source generating section that generates a power source to be supplied to the current amplification transistor, the power source generating section generating a power source of a voltage determined based on the digital data.

2. A drive signal generating apparatus according to claim 1,
wherein the digital data
indicates a voltage of the drive signal using a plurality of bits, and
wherein the power source generating section includes
a power source generating circuit that generates a plurality of power sources each having different voltages, and
a power source selection circuit that selectively supplies the plurality of power sources based on a content of a portion of bits constituting the digital data.

3. A drive signal generating apparatus according to claim 2,
wherein the digital data
is received for each of the bits,
wherein a switch circuit of the power source selection circuit
controls supply of a power source of a certain voltage in response to a voltage level indicated by the bits.

4. A drive signal generating apparatus according to claim 3,
wherein the digital data
indicates higher voltages of the drive signal using a higher order bit,
wherein the power source selection circuit
uses the higher order bit to control supply of a power source having a higher voltage than a power source whose supply is controlled by a lower order side bit than the higher order bit.

5. A drive signal generating apparatus according to claim 2,
wherein the power source selection circuit
selects a power source having a closest voltage to a voltage of the drive signal from among the power sources having voltages higher than the voltage of the drive signal.

6. A drive signal generating apparatus according to claim 1,
wherein the current amplification transistor
includes an NPN transistor whose collector is connected to a supply line of the power source that has been generated by the power source generating section, whose emitter is connected to a supply line of the drive signal, and whose base is connected to a supply line of the analog signal.

7. A liquid ejecting apparatus, comprising:
(A) an analog signal converting section that converts digital data to an analog signal;
(B) a current amplification section that generates a drive signal by amplifying a current of the analog signal, the current amplification section being provided with a current amplification transistor;
(C) a power source generating section that generates a power source to be supplied to the current amplification transistor, the power source generating section generating a power source of a voltage that has been determined based on the digital data; and
(D) a head that ejects a liquid due to application of the drive signal.

8. A drive signal generating method, comprising:
(A) generating a plurality of power sources each having different voltages;
(B) converting digital data to an analog signal;
(C) selecting based on the digital data and supplying to a current amplification transistor a power source having a corresponding voltage from among the plurality of power sources; and
(D) generating a drive signal by amplifying a current of the analog signal using the current amplification transistor.
